(19) United States
(12) Patent Application Publication
(10) Pub. No.: US 2009/0212326 A1
(43) Pub. Date: Aug. 27, 2009

(54) Hetero Field Effect Transistor and Manufacturing Method Thereof

(75) Inventor: Ken Sato, Saitama (JP)

Correspondence Address: WILMERHALE/DC, 1875 PENNSYLVANIA AVE., NW, WASHINGTON, DC, 20006, US

(73) Assignee: SANKEN ELECTRIC CO., LTD., Saitama-Ken (JP)

(21) Appl. No.: 12/390,259

(22) Filed: Feb. 20, 2009

(30) Foreign Application Priority Data
Feb. 26, 2008 (JP) 2008-043986

(51) Int. Cl. H01L 29/778; H01L 21/335

(52) U.S. Cl. 257/192; 438/172; 257/E21.403; 257/E29.246

(57) ABSTRACT

A hetero field effect transistor includes: a first semiconductor layer; a second semiconductor layer formed on the first semiconductor layer to allow a generation of a two dimensional carrier gas layer of a first conductive type on a heterojunction interface between the first semiconductor layer and the second semiconductor layer; a third semiconductor layer formed on the second semiconductor layer and having an impurity introduced therein; a source electrode formed on the third semiconductor layer; a drain electrode formed on the third semiconductor layer and separated from the source electrode; a fourth semiconductor layer formed on or above the second semiconductor layer and has a second conductive type which is different from the first conductive type; and a gate electrode electrically connected on the fourth semiconductor layer. The fourth semiconductor layer is located adjacent to and surrounded by the third semiconductor layer.

### CROSS-REFERENCE TO RELATED APPLICATIONS

This application is based upon and claims priority from Japanese Patent Application No. 2008-043986 filed on Feb. 26, 2008, the entire contents of which are incorporated herein by reference.

### BACKGROUND OF THE INVENTION

1. Technical Field

The present invention relates to a normally-off Hetero Field Effect Transistor (HFET) and a method of manufacturing the HFET.

2. Description of the Related Art

A related-art HFET includes: a semiconductor substrate made of SiC (or Si, GaN, sapphire or the like); a buffer layer made of AlN formed on the semiconductor substrate; an electron transit layer made of non-doped GaN formed on the buffer layer; an electron supply layer formed on the electron transit layer and made of a non-doped AlGaN layer or laminated layers including a non-doped AlGaN; an insulating film made from SiOx (x is an integer from 1 to 2), which is formed on the electron supply layer and a part of which is opened; and a gate electrode, a source electrode, and a drain electrode which are formed on the electron supply layer. Here, the term “non-doped” means that an impurity is not intentionally introduced into a semiconductor layer.

A band gap of AlGaN is larger than that of GaN, and a lattice constant of AlGaN is smaller than that of GaN. As a result, when the electron supply layer made of AlGaN is formed on the electron transit layer made of GaN, a tensile stress is acted on the electron supply layer and piezoelectric (voltage) depolarization occurs. Since spontaneous depolarization also occurs in the electron supply layer, an electric field caused by the piezoelectric depolarization and the spontaneous depolarization is acted on a heterojunction interface between the electron transit layer and the electron supply layer, and thus a carrier layer called as a two dimensional electron gas (2DEG) layer occurs. The 2DEG layer is used as a channel, and thus the HFET is used as a switching element which can control electron flow from the drain electrode to the source electrode through the channel therebetween.

On the other hand, in the HFET, since an energy level in the heterojunction interface between the electron transit layer and the electron supply layer is equal to or less than the Fermi level, a normally-on (depletion mode) characteristic of a negative threshold value appears. However, for example, in a semiconductor device which is applied to a power supply apparatus as a power semiconductor element, it is necessary to be a normally-off (enhancement mode) type of a positive threshold value for ensuring the safety in a malfunction. JP-A-2006-339561 describes a field effect transistor of normally-off type.

FIG. 5 is a cross-sectional view illustrating the HFET which uses a GaN-based material and has the normally-off characteristic. The HFET includes: a semiconductor substrate 101 which is made of SiC; a buffer layer 102 formed on the semiconductor substrate 101 and made of AlN; an electron transit layer 103 formed on the buffer layer 102 and made of non-doped GaN; an electron supply layer 104 formed on the electron transit layer 103 and made of non-doped AlGaN; a p-type semiconductor layer 106 formed on a part of the electron supply layer 104 and made of a p-type GaN; a high concentration p-type semiconductor layer 111 formed on the p-type semiconductor layer 106 and made of a high concentration p-type GaN; an insulating film 107 made of SiOx and formed on the electron supply layer 104, side surfaces of the p-type semiconductor layer 106, and upper surface and side surfaces of the high concentration p-type semiconductor layer 111, and a part of the insulating film 107 is opened; a gate electrode 108 made of Pd, formed on the high concentration p-type semiconductor layer 111 and is in ohmic contact with the high concentration p-type semiconductor layer 111; and a source electrode 109 and a drain electrode 110 made of Ti and Al, being separately formed on the electron supply layer 104 so as to interpose the p-type semiconductor layer 106.

Since the p-type semiconductor layer 106 made of the p-type GaN is formed on the electron supply layer 104 immediately below the gate electrode 108, the energy levels of the electron transit layer 103 and the electron supply layer 104 are increased, and thus the HFET having the normally-off characteristic is obtained.

In order to reduce an on-resistance in the HFET having the p-type gate structure, it is necessary to heighten a carrier concentration of the 2DEG layer by forming the electron supply layer 104 to be thicker, or by heightening an Al combination ratio (mole fraction) in AlGaN which constitutes the electron supply layer 104. However, in both of the manners, the on-resistance is reduced, but on the other hand, it is difficult to provide a sufficient normally off function.

In addition, when the HFET is switched at a high voltage and a high frequency, a drain current may be reduced. This phenomenon is referred to as a current collapse, and one cause of the phenomenon is that carriers are trapped in crystal defects of the semiconductor layers which constitute the HFE and are respectively made of GaN and AlGaN, so that the carrier concentration is reduced on a current path.

### BRIEF SUMMARY OF THE INVENTION

The present invention was made in consideration of the above circumstances, and an object of the present invention is to provide a Hetero Field Effect Transistor (HFET) capable of obtaining a low on-resistance, a normally-off characteristic, and a suppression of the current collapse.

According to an aspect of the invention, there is provided a hetero field effect transistor comprising: a first semiconductor layer; a second semiconductor layer formed on the first semiconductor layer to allow a generation of a two dimensional carrier gas layer of a first conductive type on a heterojunction interface between the first semiconductor layer and the second semiconductor layer; a third semiconductor layer formed on the second semiconductor layer and having an impurity introduced therein; a source electrode formed on the third semiconductor layer; a drain electrode formed on the third semiconductor layer and separated from the source electrode; a fourth semiconductor layer formed on or above the second semiconductor layer and has a second conductive type which is different from the first conductive type; and a gate electrode electrically connected on the fourth semiconductor layer, wherein the fourth semiconductor layer is located adjacent to and surrounded by the third semiconductor layer.

According to another aspect of the invention, there is provided a method of manufacturing a hetero field effect transistor that comprises a first semiconductor layer, a second semiconductor layer formed on the first semiconductor layer to allow a generation of a two dimensional carrier gas layer of a first conductive type on a heterojunction interface between the first semiconductor layer and the second semiconductor layer, a third semiconductor layer formed on the second semiconductor layer and having an impurity introduced therein, a source electrode formed on the third semiconductor layer, a drain electrode formed on the third semiconductor layer and separated from the source electrode, a fourth semiconductor layer formed on or above the second semiconductor layer and has a second conductive type which is different from the first conductive type, and a gate electrode electrically connected on the fourth semiconductor layer, wherein the fourth semiconductor layer is located adjacent to and surrounded by the third semiconductor layer, said method comprising: forming the third semiconductor layer having an impurity of the second conductive type introduced therein; and selectively activating the impurity of the third semiconductor layer to form the fourth semiconductor layer.

### BRIEF DESCRIPTION OF THE DRAWING

FIG. 1 is a cross-sectional view illustrating a structure of an HFET according to an embodiment of the present invention;

FIGS. 2A to 2D are cross-sectional views illustrating a process of a manufacturing method of the HFET according to the embodiment of the present invention;

FIG. 3 is a cross-sectional view illustrating a structure of an HFET according to another example of the embodiment of the present invention;

FIG. 4 is a cross-sectional view illustrating a structure of an HFET according to yet another example of the embodiment of the present invention; and

FIG. 5 is a cross-sectional view illustrating a structure of a related-art HFET.

### DETAILED DESCRIPTION OF THE EMBODIMENT

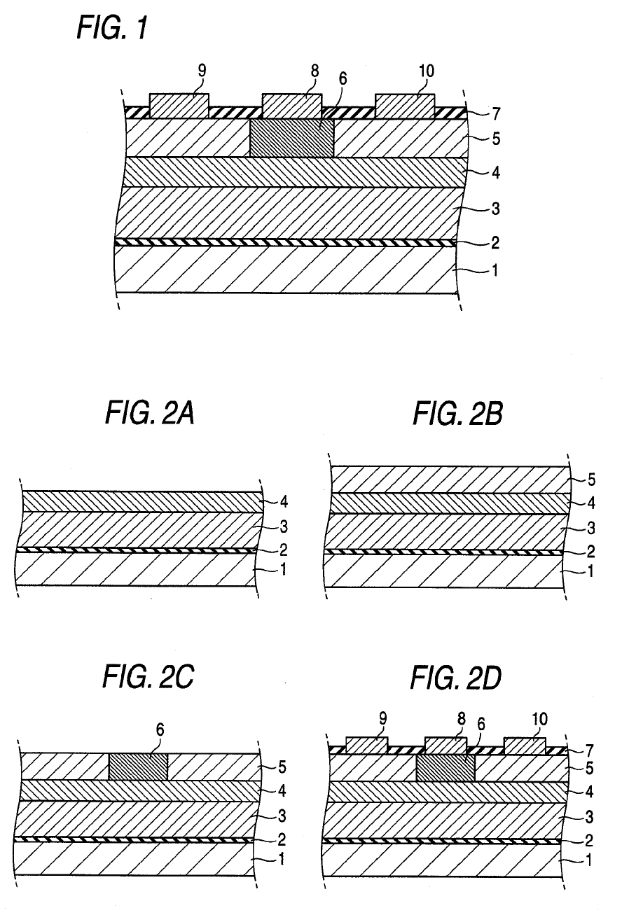

Next, an example of a semiconductor device according to an embodiment of the present invention will be described with reference to FIGS. 1 and 2.

FIG. 1 is a cross-sectional view illustrating a semiconductor device according to an embodiment of the present invention. The semiconductor device shown in FIG. 1 includes: a semiconductor substrate 1 made of SiC; a buffer layer 2 made of AlN and formed on the semiconductor substrate 1; an electron transit layer 3 made of non-doped GaN and formed on the buffer layer 2; an electron supply layer 4 made of non-doped AlGaN and formed on the electron transit layer 3; an impurity doped layer 5 made of AlGaN, formed on the electron supply layer 4, and having a p-type impurity introduced therein; a p-type semiconductor layer 6 having an activated p-type impurity and formed on the electron supply layer 4; an insulating film 7 made of SiOx and formed to cover the upper portion of the impurity doped layer 5 and the p-type semiconductor layer 6; agate electrode 8 made of Pd, formed on the p-type semiconductor layer 6, and in ohmic contact with the p-type semiconductor layer 6 in an opening of the insulating film 7; and a source electrode 9 and a drain electrode 10 made of Ti and Al, formed on the impurity doped layer 5, and connected to the impurity doped layer 5 in the opening of the insulating film 7.

An interface between the electron transit layer 3 and the electron supply layer 4 forms a heterojunction, and a two dimensional carrier layer such as 2DEG layer can be generated based on the heterojunction.

In the semiconductor device according to the embodiment of the present invention, the impurity doped layer 5 and the p-type semiconductor layer 6 are formed so as to have a substantially uniform thickness immediately below the source electrode 9 and the drain electrode 10. That is, in the semiconductor device according to the embodiment of the present invention, a region immediately below the gate electrode 8 in the impurity doped layer 5 is selectively changed to the p-type semiconductor layer 6, and a portion except for a region immediately below the gate electrode 8 in the impurity doped layer 5 remains as the impurity doped layer 5. The p-type semiconductor layer 6 is not laminated on an upper surface of the impurity doped layer 5, but is formed by selectively activating the impurity introduced into the impurity doped layer 5 as described later, and a side surface of the p-type semiconductor layer 6 is laterally adjacent to and surrounded by the impurity doped layer 5. In addition, the upper surface of the p-type semiconductor layer 6 becomes substantially flush with the upper surface of the impurity doped layer 5.

In the semiconductor device according to the embodiment of the present invention, the p-type semiconductor layer 6 has a larger area than that of the gate electrode 8 to completely include the gate electrode 8 in plan view. In other words, an area of the upper surface of the p-type semiconductor layer 6 is larger than an area of the lower surface of the gate electrode 8. Therefore, the p-type semiconductor layer 6 is extended to the outside from the outer peripheral edge of the gate electrode 8 in plan view, and the upper surface of the p-type semiconductor layer 6 is exposed in an annual shape along the outer peripheral edge of the gate electrode 8. In addition, in the semiconductor device according to the embodiment of the present invention, the impurity located at the region immediately below the gate electrode 8 is activated in an entire thickness range of the impurity doped layer 5. As a result, there is no impurity doped layer 5 in the lower surface of the p-type semiconductor layer 6, and the lower surface of the p-type semiconductor layer 6 contacts the upper surface of the electron supply layer 4. Therefore, the upper surface of the electron supply layer 4 contacts the lower surface of the p-type semiconductor layer 6 in a center region of the element and contacts with the lower surface of the impurity doped layer 5 in an outer peripheral side of the element.

FIG. 2A are cross-sectional views illustrating a process of a manufacturing method of the semiconductor device according to the embodiment of the present invention. First, as shown in FIG. 2A, the buffer layer 2 formed of AlN, the electron transit layer 3 formed of GaN, and the electron supply layer 4 formed of AlGaN are formed in this order on the semiconductor substrate 1 by epitaxial growth.

Next, as shown in FIG. 2B, the impurity doped layer 5 formed of p-type AlGaN layer are formed on the electron supply layer 4 by epitaxial growth.

Next, as shown in FIG. 2C, an impurity of a part of the impurity doped layer 5 is activated to form the p-type semiconductor layer 6, and thereafter, the insulating film 7 is formed so as to cover the impurity doped layer 5 and the p-type semiconductor layer 6.

Next, as shown in FIG. 2D, a part of the insulating film 7 is opened by a dry etching, and thereafter, the gate electrode 8, the source electrode 9, and the drain electrode 10 are formed.

Here, as the p-type impurity which is introduced into the impurity doped layer 5, Mg or the like is used. In addition, as a method for activating only a part of the impurity doped layer 5 and forming the p-type semiconductor layer 6, a method of selectively or locally irradiating a laser, an electronic ray, or the like is used. The impurity doped layer 5 selectively or locally irradiated with the laser, the electronic ray, or the like is subjected to a thermal process (annealing) and thus the p-type impurity introduced into this region is activated. On the other hand, since the impurity doped layer 5 not irradiated with the laser or the electronic ray is not subjected to the thermal process (annealing), the p-type impurity introduced into this region is not activated. The impurity doped layer 5 (in which the p-type impurity is not activated) can function as an electron supply layer. In other words, the electron supply layer 4 and the impurity doped layer 5 can function as an electron supply layer. In addition, the epitaxial growth method uses the MOCVD method, the MBE method or the like, and the dry etching uses the ICP (Inductive-Coupled Plasma) method or the like. The impurity doped layer 5 may be formed such that an AlGaN layer is formed on the electron supply layer 4 by the epitaxial growth and then the p-type impurity ions are injected. The gate electrode 8, the source electrode 9, and the drain electrode 10 may be formed before forming the insulating film 7.

According to the semiconductor device of the embodiment of the present invention, by forming the p-type semiconductor layer 6, the energy levels of the electron transit layer 3 and the electron supply layer 4 are increased, so that the normally-off characteristic is obtained.

Further, in the layer functioning as an electron supply layer (i.e., the electron supply layer 4 and the impurity doped layer 5), since a portion other than a portion located immediately below the gate electrode 8 (i.e., a portion in which the electron supply layer 4 and the impurity doped layer 5 are overlapped) are relatively thicker than the portion immediately below the gate electrode 8 (i.e., a portion of the electron supply layer 4 located immediately below the gate electrode 8), the tensile stress added to the electron supply layer is increased, and the carrier concentration of the 2DEG is increased. As a result, the on-resistance can be decreased.

According to the method of manufacturing the semiconductor device of the embodiment of the present invention, since there is no need for performing the dry etching process on the semiconductor layer immediately below the source electrode 9 and the drain electrode 10, the crystal defects in the semiconductor layer hardly occurs, and the suppression effect of the current collapse is obtained.

In the semiconductor device according to the embodiment of the present invention, the thickness of the buffer layer 2 is 100 nm; the thickness of the electron transit layer 3 is 2 μm; the thickness of the electron supply layer 4 is 25 nm; the thicknesses of the impurity doped layer 5 and the p-type semiconductor layer 6 are 100 nm; and the impurity concentration of the p-type semiconductor layer 6 is 1×10¹⁹ cm⁻³.

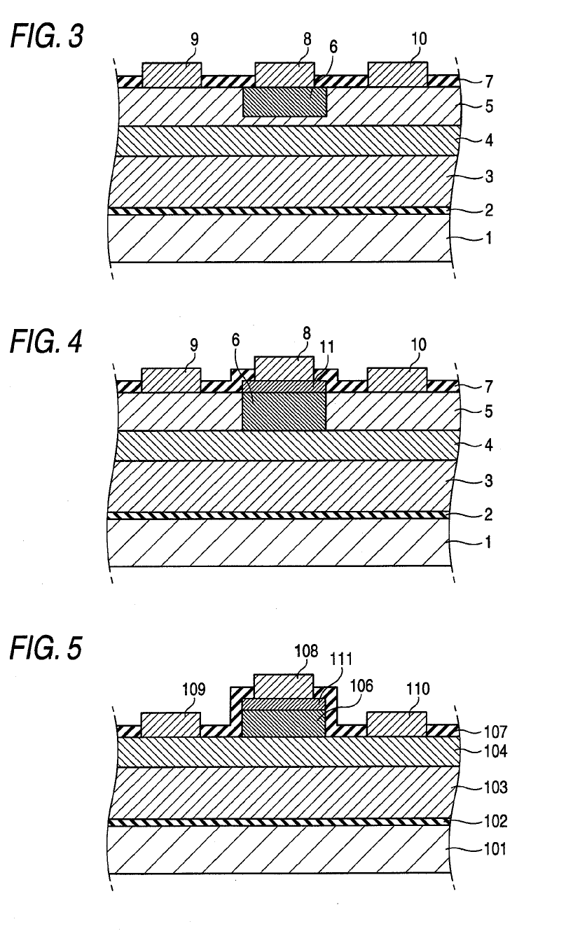

The HFET of the present invention is not limited to the above-mentioned embodiment, but various changes can be made. For example, the semiconductor substrate 1 may include Si, GaN, or sapphire. The buffer layer 2 may include a multilayered semiconductor layer which includes an AlN layer. The buffer layer 2 may not be a nitride semiconductor such as GaN etc., but may include a compound semiconductor such as GaAs or InP etc. The insulating film 7 may include SiNx (x is an integer from 1 to 2). As shown in FIG. 3, p-type semiconductor layer 6 may be formed so as not to be vertically adjacent to (not contact) the electron supply layer 4; in other words, the p-type semiconductor layer 6 may be separated from the electron supply layer via the impurity doped layer 5. Further, the upper surface of the p-type semiconductor layer 6 may be located on a plane different from the upper surface of the impurity doped layer 5. As shown in FIG. 4, a high concentration a p-type semiconductor layer 11 made, e.g., of GaN may be formed on the p-type semiconductor layer 6. In this case, the gate electrode 8 is formed on the high concentration the p-type semiconductor layer 11 to obtain a good ohmic contact, so that hole injection efficiency from the gate electrode 8 is improved. Therefore, the on-resistance can be further decreased. In addition, the source electrode 9 and the drain electrode 10 may be electrically connected to the electron supply layer 4.

According to the embodiments of the invention, it is possible to simultaneously obtain a low on-resistance, a sufficient normally-off characteristic, and a suppression of the current collapse.

What is claimed is:

1. A hetero field effect transistor comprising:
a first semiconductor layer;
a second semiconductor layer formed on the first semiconductor layer to allow a generation of a two dimensional carrier gas layer of a first conductive type on a heterojunction interface between the first semiconductor layer and the second semiconductor layer;
a third semiconductor layer formed on the second semiconductor layer and having an impurity introduced therein;
a source electrode formed on the third semiconductor layer;
a drain electrode formed on the third semiconductor layer and separated from the source electrode;
a fourth semiconductor layer formed on or above the second semiconductor layer and has a second conductive type which is different from the first conductive type; and
a gate electrode electrically connected on the fourth semiconductor layer,
wherein the fourth semiconductor layer is located adjacent to and surrounded by the third semiconductor layer.

2. The hetero field effect transistor according to claim 1,
wherein the third semiconductor layer has an impurity of the second conductive type introduced therein.

3. The hetero field effect transistor according to claim 2, further comprising a fifth semiconductor layer of the second conductive type formed on the fourth semiconductor layer and has an impurity concentration higher than that of the fourth semiconductor layer,
wherein the gate electrode is formed on the fifth semiconductor layer.

4. The hetero field effect transistor according to claim 3,
wherein the third semiconductor layer contains an inert impurity, and
wherein the fourth and fifth semiconductor layers contain an active impurity.

5. The hetero field effect transistor according to claim 1, wherein the third semiconductor layer contains AlGaN with the inert impurity, and the fourth semiconductor layer contains AlGaN with the active impurity.

6. The hetero field effect transistor according to claim 1,
wherein each of the first to fourth semiconductor layers comprises a nitride semiconductor.

7. The hetero field effect transistor according to claim 1, wherein the third semiconductor layer laterally surround the fourth semiconductor layer.

8. The hetero field effect transistor according to claim 1, wherein an upper surface of the third semiconductor layer is substantially flush with an upper surface of the fourth semiconductor layer.

9. The hetero field effect transistor according to claim 1, wherein an area of an upper surface of the fourth semiconductor layer is larger than an area of a lower surface of the gate electrode.

10. A method of manufacturing a hetero field effect transistor that comprises a first semiconductor layer, a second semiconductor layer formed on the first semiconductor layer to allow a generation of a two dimensional carrier gas layer of a first conductive type on a heterojunction interface between the first semiconductor layer and the second semiconductor layer, a third semiconductor layer formed on the second semiconductor layer and having an impurity introduced therein, a source electrode formed on the third semiconductor layer, a drain electrode formed on the third semiconductor layer and separated from the source electrode, a fourth semiconductor layer formed on or above the second semiconductor layer and has a second conductive type which is different from the first conductive type, and a gate electrode electrically connected on the fourth semiconductor layer, wherein the fourth semiconductor layer is located adjacent to and surrounded by the third semiconductor layer, said method comprising:
forming the third semiconductor layer having an impurity of the second conductive type introduced therein; and
selectively activating the impurity of the third semiconductor layer to form the fourth semiconductor layer.
